(19) United States
(12) Patent Application Publication
(10) Pub. No.: US 2023/0201829 A1
(43) Pub. Date: Jun. 29, 2023

(54) ASSEMBLIES AND METHODS

(71) Applicant: UNIVERSITEIT LEIDEN, EZ Leiden (NL)

(72) Inventors: Thomas HANKEMEIER, Leiden (NL); Anthonius Lambertus Wilhelmus MIGGIELS, Utrecht (NL); Bert WOUTERS, Haarlem (NL)

(21) Appl. No.: 17/928,339

(22) PCT Filed: May 27, 2021
(86) PCT No.: PCT/EP2021/064200

§ 371 Date: Nov. 29, 2022

(30) Foreign Application Priority Data
May 29, 2020 (GB) 2008114.7

(51) Int. Cl. B01L 3/00

(52) U.S. Cl. CPC B01L 3/50273; B01L 3/502707; B01L 2200/16; B01L 2200/0673; B01L 2300/0636; B01L 2300/168; B01L 2200/12; B33Y 80/00

(57) ABSTRACT

A fluidic assembly comprising a fluid analysis apparatus (30), the fluid analysis apparatus (30) comprising: a fluid measurement device (34); a fluidic device including a flow cell (36) arranged in a measurement region of the fluid measurement device (34), the flow cell (36) constructed of at least one first fluoropolymer material, the flow cell (36) including a channel, the channel containing a sample segment (52) that is carried in a fluorinated fluid carrier (54), wherein the sample segment (52) and fluorinated fluid carrier (54) are immiscible.

This invention relates to fluidic assemblies, methods of configuring fluid assemblies and a method of carrying out a segmented flow analysis.

High-throughput screening is used to analyse large numbers of samples in various fields such as industrial quality control, biotechnology and life sciences.

According to a first aspect of the invention, there is provided a fluidic assembly comprising a fluid analysis apparatus, the fluid analysis apparatus comprising:
a fluid measurement device;
a fluidic device including a flow cell arranged in a measurement region of the fluid measurement device, the flow cell constructed of at least one first fluoropolymer material, the flow cell including a channel, the channel containing a sample segment (also known as a ‘slug’ or ‘plug’) that is carried in a fluorinated fluid carrier, wherein the sample segment and fluorinated fluid carrier are immiscible.

According to a second aspect of the invention, there is provided a fluidic assembly comprising a fluidic device, the fluidic device including a flow cell that is formed of at least two discrete fluidly connected flow cell components, each flow cell component constructed of a first fluoropolymer material, the flow cell including a channel, the channel containing a sample segment that is carried in a fluorinated fluid carrier, wherein the sample segment and fluorinated fluid carrier are immiscible.

It will be appreciated that the fluidic device of the second aspect of the invention may be used in a range of fluidic applications, including fluid analysis and fluid processing.

The flow cell of the invention may be formed of two, three, four, five or more discrete fluidly connected flow cell components.

The at least two discrete fluidly connected flow cell components of the fluidic device of the invention may include at least one fluoropolymer transfer tubing. For example, the flow cell may include a flow cell chamber that has an inlet that is fluidly connected to an inlet fluoropolymer transfer tubing and/or has an outlet that is fluidly connected to an outlet fluoropolymer transfer tubing.

In embodiments of the second aspect of the invention, the flow cell may be formed of at least two discrete releasably and fluidly connected flow cell components and/or the flow cell may be formed of at least two discrete non-releasably and fluidly connected flow cell components. It will be understood that, in the context of a fluid connection, the scope of the term “releasable” may include non-reusable, and the scope of the term “non-releasable” may include non-reversible and non-reusable.

In preferred embodiments of the invention, the fluidic device is a microfluidic device.

Conventional flow cells for use in segmented flow are constructed out of glass that is not only susceptible to surface fouling and a high sample-to-sample carryover but also is prone to leakage due to its use of compression fittings to connect to inlet and outlet tubing. Some conventional glass flow cells are coated on the inside of their channels with fluorosilane spacer molecules. The coating process however not only is cumbersome and adds time and cost to the entire fluid procedure (e.g. fluid analysis or fluid processing) but also encounters quality issues in terms of process repeatability and reproducibility and the homogeneity of the coating on the inside of the glass flow cell's channel. In addition, due to the temporary nature of the fluorosilane coating, the coating process would have to be repeated at regular intervals. Glass flow cells are fragile, expensive and have limited design freedom in terms of geometry.

Constructing the flow cell from fluoropolymer material in accordance with the invention provides the flow cell with a channel having a permanently fluorinated surface. This allows the immiscible fluorinated fluid carrier (preferably a fluorinated liquid carrier) to preferentially wet the fluoropolymer surface of the flow cell to form a film around the fluid sample segment (preferably a liquid sample segment) during the segmented flow, thus not only providing zero-dispersion sample transfer but also reducing surface fouling and sample-to-sample carryover without requiring a regular coating process. This in turn facilities effective in-line sample transfer to reduce fluid procedure times (e.g. fluid analysis or processing times). Also, in comparison to conventional glass flow cells, the fluoropolymer-based flow cell of the invention is more robust and has a lower manufacturing cost. The resulting reductions in fluid procedure times (e.g. fluid analysis or processing times) and manufacturing costs are advantageous for high-throughput fluid procedures (e.g. high-throughput screening).

In addition to the preferential wetting characteristic, the fluorinated fluid carrier beneficially provides immiscibility between the fluorinated fluid carrier and the sample segment, chemical inertness and magnetic susceptibility matching (with water).

The fluoropolymer material of the flow cell is compatible with mass manufacturing and rapid prototyping techniques, such as additive manufacturing, 3D printing, thermoforming, compression moulding, injection moulding and machining (such as lathing, reaming and micromilling). This increases the ease of manufacturing the flow cell for different sizes and geometries that not only enables a fast iterative design process but also allows the dimensions and geometry of the fluoropolymer-based flow cell to be readily tuned so that the fluoropolymer-based flow cell can be used with a wider range of solvents in segmented flow. Moreover, the fluoropolymer-based flow cell can be readily used with a wide range of existing fluidic systems (e.g. fluid measurement or processing devices), thus removing the need to design a custom fluidic system to work with the fluoropolymer-based flow cell. Also, the fluoropolymer-based flow cell of the invention is particularly suitable for use as a vertical non-capillary flow cell that is susceptible to gravitational forces acting on a fluid inside the flow cell.

It will be appreciated that the flow cell of the invention may be constructed of a single first fluoropolymer material or may be constructed of different first fluoropolymer materials.

In embodiments of the invention, the or each first fluoropolymer material may be polychlorotrifluoroethylene (PCTFE). It will be appreciated that in principle the or each first fluoropolymer material may be any fluoropolymer material.

In further embodiments of the invention, the sample segment may be a solvent or a deuterated solvent, which may be polar or apolar.

Preferably the sample segment is non-fluorinated.

Non-limiting examples of the solvent or deuterated solvent include aromatic compounds, alcohols and ketones. Optionally the solvent or deuterated solvent may be selected from, but is not limited to, a group consisting of: water; dimethyl sulfoxide (DMSO); N,N-dimethylformamide (DMF); acetonitrile; pyridine; methanol; n-butanol; ethanol; toluene; dichloromethane (DCM); tetrahydrofuran (THF); acetone; 2-propanol; chloroform; and cyclohexane. Further optionally, when the fluoropolymer material is PCTFE, the sample segment may be selected from a list of solvents recited in https://www.polyfluor.nl/en/chemical-resistance/pctfe/. Preferably the fluoropolymer material is chemically resistant to the solvent.

In still further embodiments of the invention, the fluorinated fluid carrier may be a fluorocarbon oil carrier. Using a fluorocarbon oil carrier as the fluorinated fluid carrier broadens the applicability of the invention because the high fluorine content of the fluorocarbon oil carrier renders it immiscible with a wider range of solvents in comparison to other fluorinated fluid carriers with lower fluorine content, such as hydrofluoroether oil (e.g. HFE-7500). Whilst the other fluorinated fluid carriers with lower fluorine content may be suitable for use with polar solvents (e.g. water) as the sample segment, miscibility issues are encountered with more apolar solvents (e.g. acetone) as the sample segment.

Optionally the fluorocarbon oil carrier may be selected from, but is not limited to, a group consisting of:
1,1,2,2,3,3,4,4,4-Nonafluoro-N-(1,1,2,2,3,3,4,4,4-nonafluorobutyl)-N-(1,1,2,2-tetrafluoroethyl)butan-1-amine;
Perfluorotributylamine;
Perfluorotripentylamine;
Perfluorohexane;
Nonafluoromorpholine;
1,1,2,2,3,3,3-Heptafluoro-N,N-bis(heptafluoropropyl)-1-propanamine;
2,2,3,3,5,5,6,6-Octafluoro-4-(trifluoromethyl)morpholine;
2-(Trifluoromethyl)-3-ethoxydodecafluorohexane;
Perfluorodecalin;
Fluorinert™ FC-40;
Fluorinert™ FC-43;
Fluorinert™ FC-70;
Fluorinert™ FC-72;
Fluorinet™ FC-770;
Fluorinert™ FC-3283;
Fluorinert™ FC-3284;
3M™ Novec™ 7500 Engineered Fluid.

The fluoropolymer-based flow cell of the invention may vary in shape and configuration so long as the flow cell includes at least one channel that can contain a sample segment that is carried in a fluorinated fluid carrier where the sample segment and fluorinated fluid carrier are immiscible. Non-limiting features of the flow cell are described as follows.

The flow cell may include a single channel or a plurality of channels. In a preferred embodiment of the invention, the plurality of channels are arranged to define parallel fluid flow paths, intersecting fluid flow paths or a combination of parallel fluid flow paths and intersecting fluid flow paths through the flow cell. The parallel fluid flow paths do not intersect and are physically isolated from each other within the flow cell so that fluid is not communicated between the parallel fluid flow paths. The intersecting fluid flow paths are physically connected to each other at one or more points within the flow cell so that fluid is communicated between the intersecting fluid flow paths.

Preferably the plurality of channels are formed in a monolithic flow cell structure.

The number of channels in the flow cell depends on the requirements of the fluid procedure (e.g. fluid analysis or processing procedure), such as flow properties of the sample segment and fluorinated fluid carrier. Due to the fluoropolymer material of the flow cell resulting in the ease of manufacturing the flow cell for different sizes and geometries, the number of channels in the flow cell can be readily modified to suit a particular fluidic system, such as a fluid processing device, fluid measurement device or fluid analysis apparatus.

The inventors have found that, in segmented flow, reducing the characteristic length (e.g. internal width or diameter) of the fluoropolymer-based flow cell enables the use of the flow cell with a wider range of solvents for fluid procedures (e.g. fluid analysis or processing) but at the risk of loss of mass sensitivity. Using a multi-channel flow cell compensates for any loss of mass sensitivity arising from the reduction in characteristic length while retaining the capability of the fluoropolymer-based flow cell to be used with a broad range of types of solvents in segmented flow.

A maximum characteristic length of the channel may be limited by the Bond number, which increases with characteristic length of the channel. In embodiments of the invention, the sample segment, the fluorinated fluid carrier and a characteristic length of the channel may be selected to correspond to a Bond number that corresponds to the sample segment staying intact as it is carried by the fluorinated fluid carrier through the channel. Preferably the Bond number is lower than 4.0.

The Bond number Bo is related to the Eötvös number Eö and the Confinement number Co. The relationship between the Bond number Bo, the Eötvös number Eö and the Confinement number Co is well-known in the art. The critical Bond number describe the trade-off between gravitational and interfacial forces and defines the micro-to-macro scale transition point that affects the flow behaviour of the sample segment in the flow cell.

The configuration of the fluoropolymer-based flow cell of the invention provides the flexibility to choose from various sample segments, various fluorinated fluid carriers and a range of characteristic lengths of the channel in order to correspond to a Bond number that is conducive to reliable segmented flow. In addition, the reduction in surface fouling and sample-to-sample carryover by the flow cell of the invention ensures consistent segmented flow behaviour across different sample segment-fluorinated fluid carrier segmented flow systems. This not only greatly increases the applicability of the invention to a wider range of fluid applications (e.g. fluid analysis or processing applications) but provides the ability to design and/or predict a suitable combination of the sample segment, the fluorinated fluid carrier and the characteristic length of the channel for segmented flow.

A maximum characteristic length of the channel may be limited by several factors, such as the thickness of the fluoropolymer-based flow cell and the physical confines of the associated fluidic system in which the flow cell is to be used or incorporated (e.g. the measurement region of the fluid measurement device). As stated above, reducing the characteristic length of the fluoropolymer-based flow cell enables the use of the flow cell with a wider range of solvents for fluid procedures (e.g. fluid analysis or processing).

In embodiments of the first aspect of the invention, the flow cell may be formed of at least two discrete fluidly connected flow cell components, each flow cell component constructed of a first fluoropolymer material. In such embodiments, the flow cell may be formed of at least two discrete releasably and fluidly connected flow cell components and/or the flow cell may be formed of at least two discrete non-releasably and fluidly connected flow cell components. As mentioned above, the flow cell of the invention may be formed of two, three, four, five or more discrete fluidly connected flow cell components. As also mentioned above, the at least two discrete fluidly connected flow cell components of the fluidic device of the invention may include at least one fluoropolymer transfer tubing. For example, the flow cell may include a flow cell chamber that has an inlet that is fluidly connected to an inlet fluoropolymer transfer tubing and/or has an outlet that is fluidly connected to an outlet fluoropolymer transfer tubing.

In still further embodiments of the invention, the flow cell may comprise:
a flow cell inlet connector defining an inlet for, preferably releasable, fluid connection to a first fluid conduit;
a flow cell outlet connector defining an outlet for, preferably releasable, fluid connection to a second fluid conduit; and
a flow cell chamber including a intermediate chamber (e.g. a measurement or processing chamber) arranged between inlet and outlet portions, the inlet portion of the flow cell chamber fluidly connected to the flow cell inlet connector, the outlet portion of the flow cell chamber fluidly connected to the flow cell outlet connector.

In such embodiments, the inlet portion of the flow cell chamber may be releasably and fluidly connected to the flow cell inlet connector, and/or the outlet portion of the flow cell chamber may be releasably and fluidly connected to the flow cell outlet connector.

Due to the use of fluoropolymer material to construct the flow cell, releasable fluid connections of the flow cell chamber to the flow cell inlet and outlet connectors may be formed in various ways to improve their reliability through better pressure resistance as opposed to the compression fittings used with conventional glass flow cells. This has the effect of reducing the risk of leakage, thus allowing the use of higher flow rates to speed up fluid procedure times and enabling the use of the invention with a wider range of fluid applications and equipment.

The material properties of the fluoropolymer material of the flow cell of the invention readily facilitate the design or modification of the flow cell inlet connector, the flow cell outlet connector and/or the flow cell chamber to create the releasable fluid connections.

Non-limiting examples of releasable fluid connections of the flow cell chamber to the flow cell inlet and outlet connectors are set out as follows.

The inlet portion of the flow cell chamber may be press fit into the flow cell inlet connector. Alternatively the flow cell inlet connector may be press fit into the inlet portion of the flow cell chamber. Further alternatively the inlet portion of the flow cell chamber may be threadably connected to the flow cell inlet connector.

The outlet portion of the flow cell chamber may be press fit into the flow cell outlet connector. Alternatively the flow cell outlet connector may be press fit into the outlet portion of the flow cell chamber. Further alternatively the outlet portion of the flow cell chamber may be threadably connected to the flow cell outlet connector.

The press fit connection may include a ridge and groove pattern provided on a surface of one of the connected components to ensure a better leak-resistant and mechanically stable fit.

A bore of the inlet portion of the flow cell chamber may include a first bore section that tapers in a direction away from the intermediate chamber. Alternatively a bore of the flow cell inlet connector may include a first bore section that tapers in a direction away from the intermediate chamber.

A bore of the outlet portion of the flow cell chamber may include a second bore section that tapers in a direction away from the intermediate chamber. Alternatively a bore of the flow cell outlet connector may include a second bore section that tapers in a direction away from the intermediate chamber.

The inclusion of the tapered bore section(s) in the flow cell help to preserve the integrity of the sample segment by providing a gradual dimensional transition during the entry and/or exit of the sample segment into and/or out of the chamber. Otherwise a sudden dimensional transition could lead to dispersion and breakup of the sample segment and poorly-permeated zones in corners at the entrance and/or exit of the chamber.

In other embodiments of the invention, the flow cell inlet connector may be formed as a first frame portion, the flow cell outlet connector may be formed as a second frame portion, and the first and second frame portions may be engageable with each other to form a frame for holding the flow cell chamber between the flow cell inlet and outlet connectors.

In use, an inlet of the fluidic device (e.g. an inlet of the flow cell) is fluidly coupled to a first fluid conduit for transfer of a fluid into the fluidic device, and an outlet of the fluidic device (e.g. an outlet of the flow cell) is fluidly coupled to a second fluid conduit for transfer of the fluid out of the fluidic device.

Preferably the fluidic assembly may include first and second fluid conduits constructed of a second fluoropolymer material, wherein an inlet of the fluidic device (e.g. an inlet of the flow cell) is fluidly coupled to the first fluid conduit, and an outlet of the fluidic device (e.g. an outlet of the flow cell) is fluidly coupled to the second fluid conduit. It will be appreciated that the first and second fluid conduits may be constructed of the same second fluoropolymer material or may be constructed of different second fluoropolymer materials.

The fluoropolymer fluid conduits combine with the fluoropolymer-based flow cell to provide a fluoropolymer-based fluidic path that further enhances the segmented flow due to the preferential wetting by the fluorinated oil carrier and the chemical inertness of the fluoropolymer materials that is compatible with a wide range of solvents as the sample segment.

Optionally the second fluoropolymer material may be a thermoplastic fluoropolymer material. Optionally the second fluoropolymer material may be selected from, but is not limited to, a group consisting of: fluorinated ethylene propylene; polytetrafluoroethylene; polyvinylidenefluoride; ethylene tetrafluoroethylene; tetrafluoroethylene hexafluoropropylene vinylidene fluoride; and perfluoroalkoxy alkane.

The invention is applicable to a wide range of fluidic applications and equipment, particularly those requiring high-throughput screening and monitoring, across various fields such as metabolomics, biobanks and biorepositories.

The fluid measurement device may be a nuclear magnetic resonance (NMR) spectrometer. The improved segmented flow resulting from the configuration of the fluoropolymer-based flow cell of the invention has specific advantages for NMR spectroscopy. In particular, the reduced fluid analysis times arising from the use of fluoropolymer material to construct the flow cell of the invention enables high-throughput NMR screening, reaction monitoring and the hyphenation of liquid chromatography with NMR.

According to a third aspect of the invention, there is provided a method of configuring a fluid analysis apparatus, the fluid analysis apparatus in accordance with any one of the first aspect of the invention and its embodiments, the method comprising the steps of:
providing a fluid measurement device;
providing a flow cell constructed of at least one first fluoropolymer material, the flow cell including a channel;
arranging the flow cell in a measurement region of the fluid measurement device; and
supplying a sample segment carried in a fluorinated fluid carrier into the channel of the flow cell, wherein the sample segment and fluorinated fluid carrier are immiscible.

The features and advantages of the first aspect of the invention and its embodiments apply mutatis mutandis to the features and advantages of the method of the third aspect of the invention and its embodiments.

According to a fourth aspect of the invention, there is provided a method of carrying out a segmented flow analysis, the method comprising the steps of: configuring a fluid analysis apparatus in accordance with any one of the third aspect of the invention and its embodiments; and operating the fluid measurement device to perform a measurement on the sample segment in the channel of the flow cell.

The features and advantages of the first and third aspects of the invention and their embodiments apply mutatis mutandis to the features and advantages of the method of the fourth aspect of the invention and its embodiments.

According to a fifth aspect of the invention, there is provided a method of configuring a fluidic assembly, the fluidic assembly in accordance with any one of the second aspect of the invention and its embodiments, the method comprising the steps of: providing a fluidic device, the fluidic device including a flow cell that is formed of at least two discrete fluidly connected flow cell components, each flow cell component constructed of a first fluoropolymer material, the flow cell including a channel; and supplying a sample segment carried in a fluorinated fluid carrier into the channel of the flow cell, wherein the sample segment and fluorinated fluid carrier are immiscible.

The features and advantages of the second aspect of the invention and its embodiments apply mutatis mutandis to the features and advantages of the method of the fifth aspect of the invention and its embodiments.

The methods of the invention may include the step of performing a machining process (e.g. lathing, reaming, micromilling) or an additive manufacturing or 3D printing process or an injection moulding, compression moulding or thermoforming process to construct at least one flow cell component of the flow cell from the or each first fluoropolymer material. This step may be used to construct one or more fluoropolymer-based flow cell components of the flow cell to have a simple internal structure (such as a single channel) or a complex internal structure (such as multiple discrete channels or a network of channels). This step is particularly useful for the manufacture of a fluoropolymer-based flow cell having a plurality of channels, particularly where the plurality of channels are formed in a monolithic flow cell structure.

Different parts of the flow cell, e.g. the discrete flow cell components, may be manufactured using the same fabrication process or may be respectively manufactured using different fabrication processes.

It will be appreciated that the use of the terms “first” and “second”, and the like, in this patent specification is merely intended to help distinguish between similar features (e.g. the first and second fluoropolymer materials, the first and second fluid conduits, the first and second bore sections, etc.), and is not intended to indicate the relative importance of one feature over another feature, unless otherwise specified.

Within the scope of this application it is expressly intended that the various aspects, embodiments, examples and alternatives set out in the preceding paragraphs, and the claims and/or the following description and drawings, and in particular the individual features thereof, may be taken independently or in any combination. That is, all embodiments and all features of any embodiment can be combined in any way and/or combination, unless such features are incompatible. The applicant reserves the right to change any originally filed claim or file any new claim accordingly, including the right to amend any originally filed claim to depend from and/or incorporate any feature of any other claim although not originally claimed in that manner.

Preferred embodiments of the invention will now be described, by way of non-limiting examples, with reference to the accompanying drawings in which:

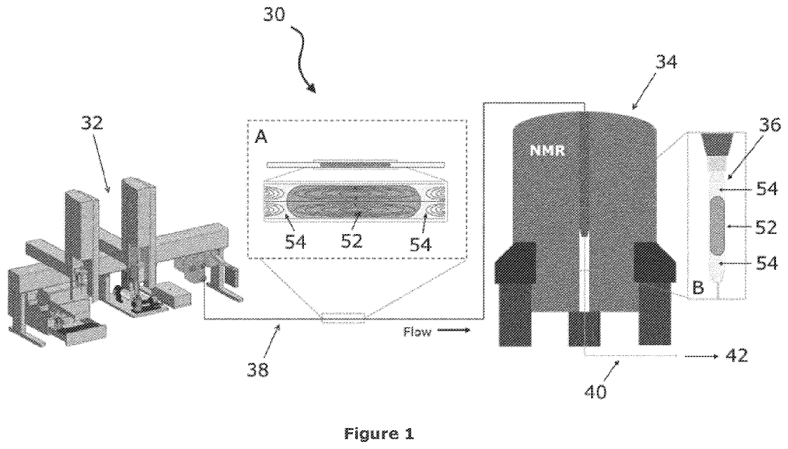

FIG. 1 shows a schematic overview of a fluid analysis apparatus according to a first embodiment of the invention;

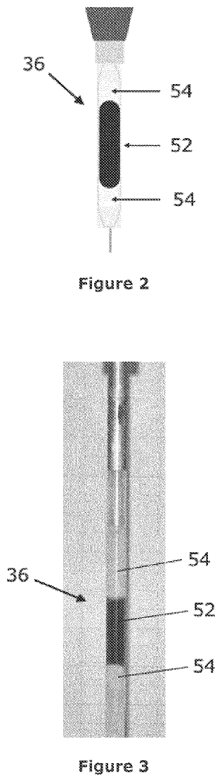

FIGS. 2 to 5 show a flow cell of the fluid analysis apparatus of FIG. 1;

FIGS. 6 and 7 show sample-to-sample carryover data for a range of samples;

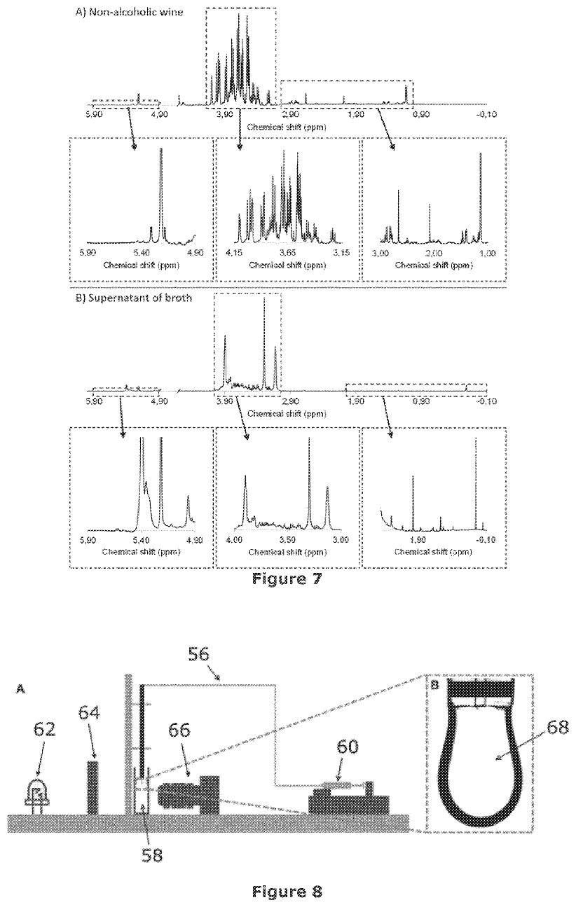

FIG. 8 shows a pendant-drop tensiometry set-up;

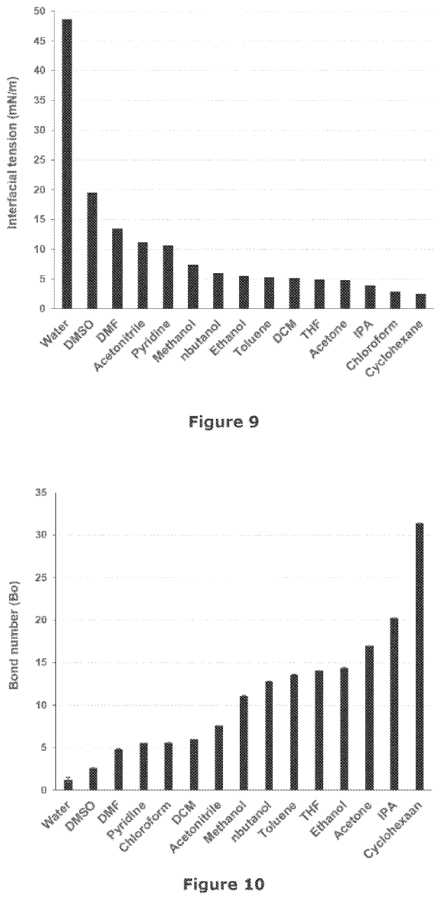

FIG. 9 shows interfacial tension data for a range of solvents;

FIG. 10 shows Bond number data for a range of solvents;

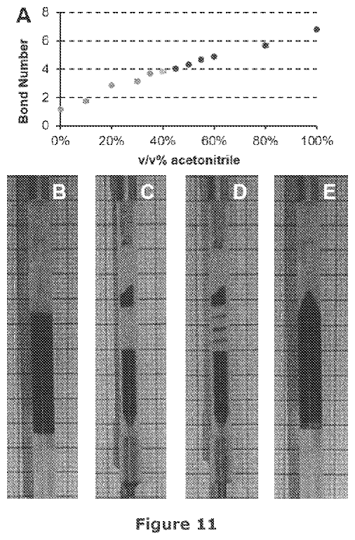

FIG. 11 shows calculated Bond numbers for different acetonitrile-water mixtures and flow regimes for sample segments at different Bond numbers;

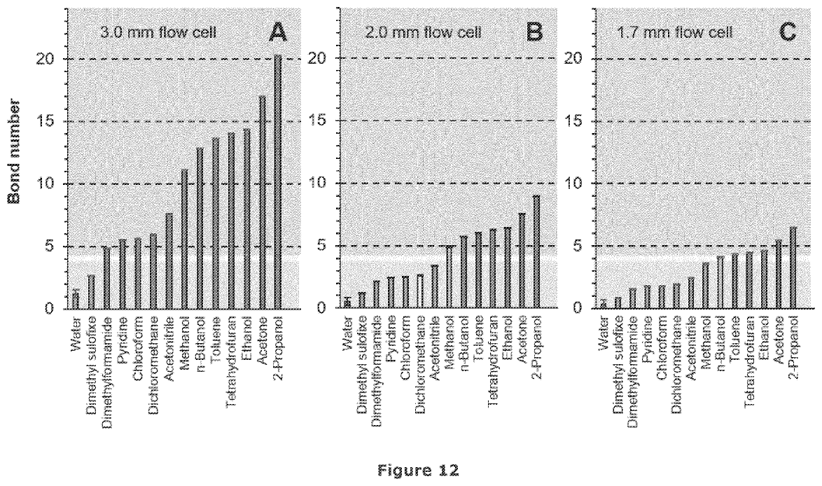

FIG. 12 shows Bond number data for a range of solvents in flow cells with various channel inner diameters;

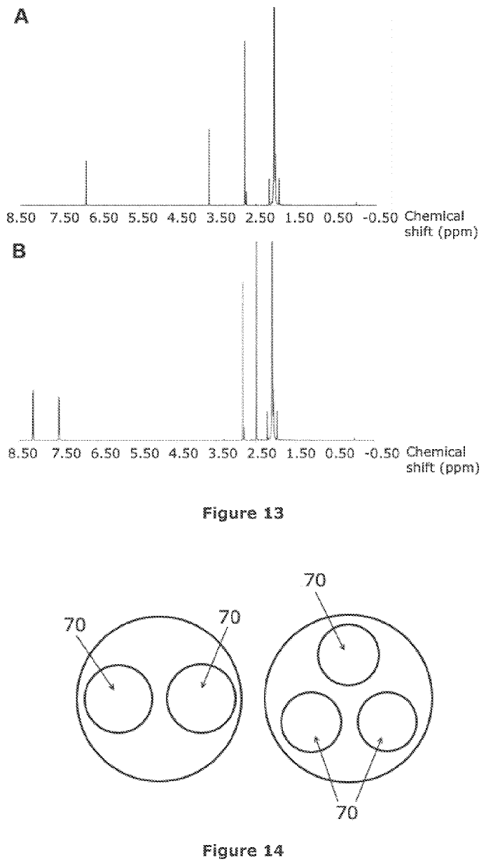

FIG. 13 shows overlaid spectra for different samples dissolved in acetone;

FIG. 14 shows cross-sectional views of different flow cells;

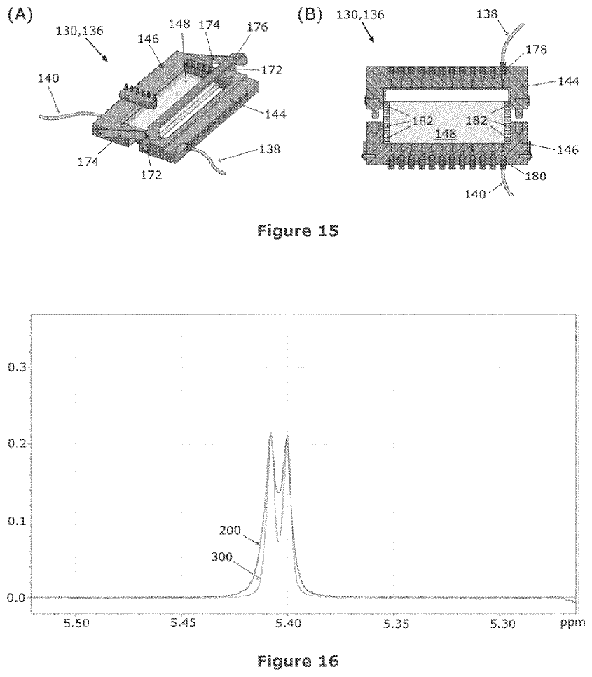

FIG. 15 shows a microfluidic device according to a second embodiment of the invention; and

FIG. 16 shows overlaid spectra for a sample in different flow cells.

The figures are not necessarily to scale, and certain features and certain views of the figures may be shown exaggerated in scale or in schematic form in the interests of clarity and conciseness.

To illustrate the working of the invention, the invention is described with reference to its use as part of an automated sample-transfer platform coupled to a flow-NMR spectrometer, where samples are transferred and positioned in a fluoropolymer-based flow cell for stop-flow analysis by the use of segmented flow. Whilst the following embodiment of the invention is described with reference to high-throughput flow-NMR spectroscopy, it will be appreciated that the following embodiment of the invention is applicable mutatis mutandis to other NMR spectrometers and NMR spectroscopy (such as micro-coil NMR and benchtop NMR) and other fluid analysis equipment and applications.

Automated flow-NMR not only avoids manual sample handling and improves sample tracking, thus minimising the risk of human error or sample degradation, but also offers fast times from sample preparation to data acquisition, which is especially important in the case of fast NMR screening of a large number of samples. Risks associated with automated flow-NMR include increased complexity of the sample-transfer platform, surface fouling and sample-to-sample carryover in the flow cell and the possibility of a leak inside a probe of the NMR spectrometer.

A fluid analysis apparatus according to a first embodiment of the invention is shown in FIG. 1 and is designated generally by the reference numeral 30.

The fluid analysis apparatus 30 comprises a CTC PALS Dual-Head Robot RTC/RSI 160 cm robotic autosampler 32, a Bruker UltraShield 500 MHz NMR spectrometer 34 fitted with a flow probe, a flow cell 36, an inlet transfer tubing 38 and an outlet transfer tubing 40.

The flow cell 36 is inserted inside the flow probe to be within a measurement region of the NMR spectrometer 34. Outer dimensions of the flow cell 36 are designed to fit inside a bore of the flow probe. A centre of a measurement chamber of the flow cell 36 is aligned at midplane of a magnetic field and a radio frequency (RF) coil of the NMR spectrometer. The measurement chamber exemplarily has an inner diameter of 3.0 mm.

The inlet transfer tubing 38 fluidly couples the robotic autosampler 32 to an inlet of the flow cell 36 so that a fluid can be transferred from the robotic autosampler 32 into the flow cell 36. The outlet transfer tubing 40 fluidly couples an outlet of the flow cell 36 to a waste fluid container 42 so that a fluid can be transferred out of the flow cell 36 to the waste fluid container 42. The inlet transfer tubing 38 is constructed of fluorinated ethylene propylene (FEP), while the outlet transfer tubing 40 is constructed of polyetheretherketone (PEEK). The inlet transfer tubing 38 exemplarily has a 1/32″ outer diameter, a 254 μm inner diameter and a length of 3-4 m. The outlet transfer tubing 40 exemplarily has a 1/32″ outer diameter, a 380 μm inner diameter and a length of 3 m.

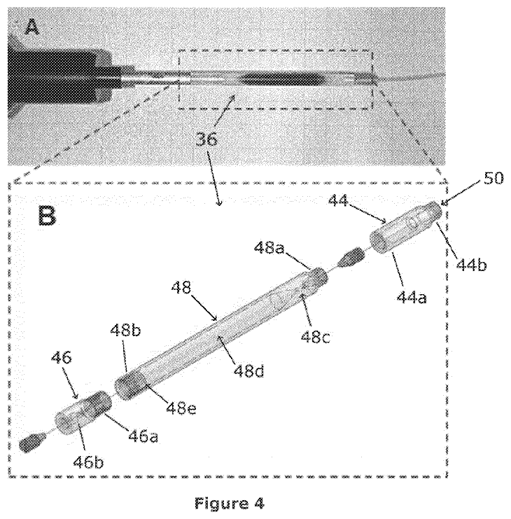

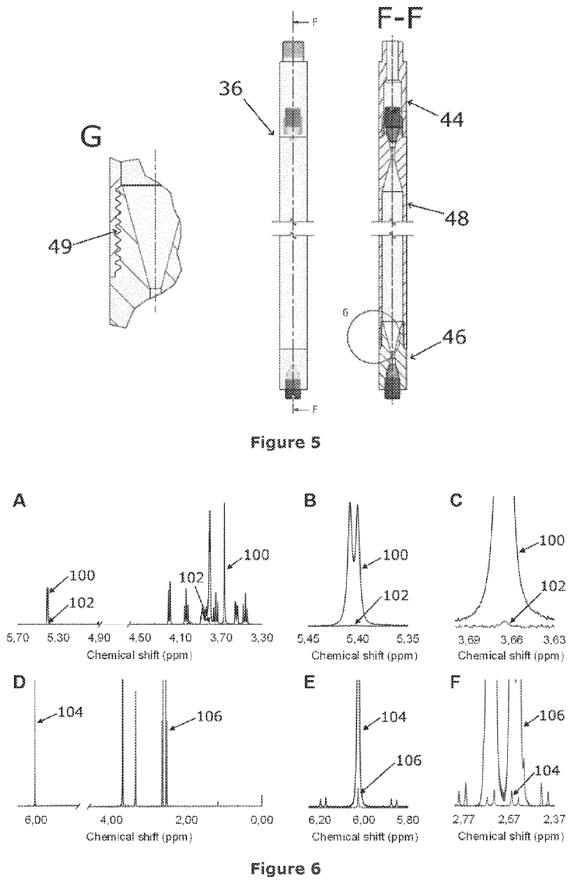

FIG. 2 shows a close-up view of the flow cell 36 shown in Inset B of FIG. 1. FIG. 3 shows a photograph of an actual flow cell 36. FIG. 4 shows an exploded view of the flow cell 36. FIG. 5 shows cross-sectional views of the flow cell 36.

The flow cell 36 is constructed of polychlorotrifluoroethylene (PCTFE). As shown in FIG. 4, the flow cell 36 consists of three separate interlocking pieces in the form of a flow cell inlet connector 44, a flow cell outlet connector 46 and a flow cell chamber 48. Each interlocking piece is generally shaped as a cylindrical tube having a respective bore.

A first, threaded female end 44a of the flow cell inlet connector 44 is screwed onto a first, threaded male end 48a of the flow cell chamber 48. The threaded connection ensures a leak-resistant and mechanically stable fit. The bore of the flow cell inlet connector 44 includes, from the first end 44a to the opposite second end 44b of the flow cell inlet connector, a straight bore section followed by a narrower straight bore section. The inlet transfer tubing 38 extends through the bore of the flow cell inlet connector 44.

The flow cell chamber 48 includes, from its first end 48a to its opposite second end 48b, an inlet portion 48c, an intermediate measurement chamber 48d and an outlet portion 48e, where the bore of the flow cell chamber 48 extends through the inlet portion 48c, the measurement chamber 48d and the outlet portion 48e. The bore of the flow cell chamber 48 includes, from the first end 48a to the second end 48b of the flow cell chamber 48, a straight bore section followed by a tapered conical bore section that tapers in a direction away from the second end 48b and towards the first end 48a in the inlet portion 48c followed by another straight bore section extending through the measurement chamber 48d and outlet portion 48e. The inlet transfer tubing 38 is received in the straight bore section in the inlet portion 48c of the flow cell chamber 48 using a one-piece nut-and-ferrule connection, from which the hex nut was removed, to ensure a pressure-resistant and minimal dead volume connection.

A first, male end 46a of the flow cell outlet connector 46 is press fit into the second, female end 48b of the flow cell chamber 48. A ridge and groove pattern 49 is provided on the first end 46a of the flow cell outlet connector 46 to ensure a leak-resistant and mechanically stable fit. The bore of the flow cell outlet connector 46 includes, from the first end 46a to the opposite second end 46b of the flow cell outlet connector 46, a tapered conical bore section that tapers in a direction away from the first end 46a and towards the second end 46b followed by a straight bore section. The outlet transfer tubing 40 is received in the straight bore section of the flow cell outlet connector 46 using a one-piece nut-and-ferrule connection, from which the hex nut was removed, to ensure a pressure-resistant and minimal dead volume connection.

In this way the bores of the flow cell inlet connector 44, flow cell outlet connector 46 and flow cell chamber 48 combine to define a channel 50 of the flow cell 36 that is used to contain the segmented flow.

The segmented flow is created by introducing one or more sample segments 52 (‘slugs’ or ‘plugs’) into a continuous flow of fluorinated oil carrier 54, exemplarily Fluorinert® FC-72 oil, so that the or each sample segment 52 is bracketed by the FC-72 oil 54. Multiple sample segments 52 may be introduced into the FC-72 oil 54 to form a sequence (“train”) of discrete sample segments 52, where each of the multiple sample segments 52 is bracketed by the FC-72 oil 54. For reasons of conciseness, the invention will be described hereinafter with reference to a single sample segment 52 but it will be understood that the invention applies mutatis mutandis to a sequence of multiple sample segments 52. The sample segment 52 and FC-72 oil 54 are immiscible to enable segmented flow. The sample segment 52 is transferred from the robotic autosampler 32 into the flow cell 36, by way of displacement by a discrete volume of FC-72 oil 54 through the inlet transfer tubing 38. The sample segment 52 is positioned inside the measurement chamber 48d of the flow cell 36 to enable stop-flow analysis of the sample segment 52 by the NMR spectrometer 34, such as rapid screening 1D NMR analysis. When the sample segment 52 is in position inside the measurement chamber 48d, temperature equilibration may be carried out for a set period of time before carrying out the stop-flow analysis. After the measurement is complete, the sample segment 52 is then transferred out of the flow cell to the waste fluid container 42.

Insets A and B in FIG. 1 show respective segmented flows inside the inlet transfer tubing 38 and inside the flow cell 36.

Preferably a back-pressure regulator (typically 5 psi) is connected to the outlet transfer tubing 40 to give a constant pressure resistance to a pump of the autosampler 32. This prevents leakage of fluid from the flow cell 36 during the stop-flow analysis due to hydrostatic pressure and evaporation of the volatile FC-72 oil 54 at the open end of the outlet transfer tubing 40.

The fluid analysis apparatus 30 was evaluated for sucrose, maleic acid and citrate. FIG. 6 illustrates representative 500 ¹H MHz NMR overlaid spectra of intercalating injections of a sucrose sample 100 and a blank sample 102 (FIG. 6A) and intercalating injections of a maleic acid sample 104 and a citrate sample 106 (FIG. 6D). The insets in FIGS. 6B and 6C show the sample-to-sample carry-over for the selected regions from FIG. 6A, while the insets in FIGS. 6E and 6F show the sample-to-sample carry-over for the selected regions from FIG. 6A. The residual water peak was cut from the spectra between 4.6-4.9 ppm. All peaks are referenced to the resonance of DSS at 0 ppm. Table 1 summarises the data collected for chemical shift signals, half-height peak widths, signal-to-noise ratios, relative standard deviation peak areas and sample-to-sample carryovers.

The 50% linewidth of the deconvoluted doublet at 5.40 ppm in the 5 mM sucrose samples was used as a benchmark and resulted in a linewidth of 2.5 Hz (FIG. 3B). For the sucrose samples (n=23), sample-to-sample carryover at the H1 signal at 3.66 ppm was as low as 0.6% (FIG. 6C). In the case of the H1 doublet at 5.40 ppm (FIG. 6B), the blank samples were below the limit of detection under these measurement conditions, which means that sample-to-sample carryover is negligible in practical terms.

For the citrate and maleic acid samples (FIGS. 6D-F), the sample-to-sample carryover was found to be 0.4% and 0.6% respectively. The repeatability was assessed by calculating the relative standard deviations of selected integrated peak areas (n=25). For the sucrose, maleic acid and citrate samples, the relative standard deviation of the peak areas is between 0.5% and 1.2%, thereby demonstrating that the fluid analysis apparatus 30 allows for repeatable sample analysis.

TABLE 1

| | | | | Relative | |
|---|---|---|---|---|---|
| | Chemical | Half-height | Signal- | standard | |
| | shift | peak | to- | deviation | Carryover |
| Sample | signal | width | noise | peak area | (%) |
| type | (ppm) | (Hz) | ratio | (%) (n = 25) | (n = 25) |
| 5 mM | 3.66 | 2.6 | 770 | 1.2 | 0.6 |
| sucrose | | | | | |
| 5 mM | 5.40 | 2.5 | 200 | 0.5 | n/a |
| sucrose | | | | | |
| Citrate | 2.62 | 1.6 | 6325 | 0.9 | 0.4 |
| Maleic | 6.03 | 1.8 | 3120 | 0.6 | 0.6 |
| acid | | | | | |

The sucrose sample solutions consisted of 171 mg sucrose and 2.5 mg (trimethylsilyl)-1-propanesulfonic acid-d6 sodium salt (DSS-D6) dissolved in 100 mL deuterium oxide (D20). The maleic acid/ethylenedinitrilotetraacetic (EDTA) sample solution consisted of 200 mg maleic acid, 400 mg EDTA disodium and 5 mg DSS-D6 dissolved in 10 mL deuterium oxide (pH adjusted to 6.40), which was then diluted up to 100 mL with purified and deionised water. The citrate solution consisted of 500 mg trisodium citrate and 10 mg Sodium 2,2-dimethyl-2-silapentane-5-sulfonate (DSS), dissolved in 100 mL deuterium oxide. Blank solutions consisted of 2.5 mg DSS-D6 dissolved in 100 mL deuterium oxide.

Complex samples were assessed for repeatability, mass sensitivity and sample-to-sample carryover to demonstrate the capabilities of the fluid analysis apparatus 30 for high-throughput analysis. Representative 500 MHz ¹H NMR spectra are shown in FIG. 7 for complex multi-component samples, namely non-alcoholic wine (FIG. 7A) and broth supernatant (FIG. 7B) and the results are summarised in Table 2. Zoom-ins of selected regions are shown below the full spectra. The residual water peak was cut from the spectra between 4.6-4.9 ppm. All peaks are referenced to the resonance of DSS at 0 ppm. The complex samples occasionally showed slightly higher sample-to-sample carry-over than the above aqueous samples with reference to FIG. 6 and Table 1: 0.9-1.1% for broth supernatant and 0.4-0.8% for non-alcoholic wine. The slight increase in sample-to-sample carry-over may be explained by the presence of more apolar metabolites and polysaccharides in these samples. Signal-to-noise ratios for selected peaks varied from 275 to 2520 and half-height peak widths varied between 1.9 and 2.3 Hz. The repeatability was shown to be good, with relative standard deviations in the peak areas in the range of 0.2-1.5.

TABLE 2

| | | | | Relative | |
|---|---|---|---|---|---|
| | Chemical | Half-height | Signal- | standard | |
| | shift | peak | to- | deviation | Carryover |
| Sample | signal | width | noise | peak area | (%) |
| type | (ppm) | (Hz) | ratio | (%) (n = 10) | (n = 10) |
| Wine | 4.02 | 2.2 | 2520 | 1.1 | 0.7 |
| Wine | 3.47 | 2.2 | 570 | 1.1 | 0.4 |
| Wine | 2.07 | 1.9 | 275 | 1.5 | n/a |
| Broth | 5.40 | n/a | 325 | 0.4 | 1.0 |
| Broth | 3.29 | n/a | 2030 | 0.2 | 0.8 |
| Broth | 2.04 | 1.9 | 295 | 1.3 | 1.1 |
| Broth | 0.20 | 2.3 | 495 | 0.8 | 0.9 |

The non-alcoholic wine samples were lyophilized overnight and dissolved to the original volume in deuterium oxide supplemented with 25 mg/L DSS-D6 as the chemical shift reference. The broth samples represent supernatant after microbial cell-lysis and centrifugation. After addition of internal standard FSP (1,1-difluoro-1-trimethylsilanyl methyl phosphonic acid), the supernatant was freeze-dried, and the lyophilized material was subsequently dissolved in deuterium oxide. DSS was used as the chemical shift reference.

The configuration of the fluid analysis apparatus 30 of FIG. 1 therefore results in a fluid analysis apparatus 30 for use in segmented flow in an automated sample-transfer platform capable of high-throughput flow-NMR screening of large numbers of samples.

The permanently fluorinated surfaces of the channel 50 of the flow cell 36 and transfer tubing 38,40 enables preferential wetting of the fluorinated surfaces by the FC-72 oil 54 to form a film around the sample segment 52 during the segmented flow. This not only provides zero-dispersion sample transfer but also reduces surface fouling and sample-to-sample carryover, which in turn facilities effective in-line sample transfer to reduce fluid analysis times. Low sample-to-sample carryover is essential in flow-NMR analysis to ensure high data quality and for quantitation. In comparison to conventional glass flow cells, the fluoropolymer-based flow cell 36 is more robust, has a lower manufacturing cost, is compatible with mass manufacturing and rapid prototyping techniques, can be readily used with a wide range of existing fluid measurement devices and offers improved material properties in the form of the permanently fluorinated surface that is compatible with a wider range of solvents in segmented flow.

In addition, the FC-72 oil 54 beneficially provides immiscibility between the FC-72 oil 54 and the sample segment 52, chemical inertness and magnetic susceptibility matching (with water). In comparison, segmented flow using air as a carrier fluid may have the robustness of its sample transfer compromised by the compressibility and large thermal expansion coefficient of air. The magnetic susceptibility is different from that of the liquid sample segment, and air bubbles can significantly distort the fluid analysis. Finally, segmented flow with air still requires extensive rinsing against sample-to-sample carryover.

Biphasic segmented flow for two immiscible fluid phases in tubing and channels is characterised by four dominant forces: gravitational force, viscous force, inertial force, and surface tension (i.e. interfacial tension). The relative importance of these four forces is described by dimensionless numbers including:
the Reynolds number (Re) that is a measure of the inertial force acting on the fluid relative to the viscous force acting on the fluid and is given by:

$$Re = \frac{u \cdot ρ \cdot D}{μ}$$

the Capillary number (Ca) that is a measure of the viscous force acting on the fluid relative to the surface tension between the dispersed and continuous fluid phases and is given by:

$$Ca = \frac{μ \cdot u}{σ}$$

the Weber number (We) that is a measure of the inertial force acting on the fluid relative to the surface tension between the dispersed and continuous fluid phases and is given by:

$$We = \frac{{u}^{2} \cdot ρ \cdot D}{σ}$$

where the Bond number (Bo) that is a measure of the gravitational force acting on the fluid relative to the surface tension between the dispersed and continuous fluid phases and is given by:

$$Bo = \frac{Δ ρ \cdot g \cdot {D}^{2}}{σ}$$

Where u is the flow speed (ms⁻¹), ρ is the density of the fluid (kgm⁻³), D is a characteristic dimension (m), p is the dynamic viscosity of the fluid (kgm⁻¹s⁻¹), σ is the surface tension between the dispersed and continuous fluid phases (Nm⁻¹), Δρ is the difference in densities between the dispersed and continuous fluid phases (kgm⁻³) and g is the gravitational acceleration (ms⁻²).

The flow behaviour of the biphasic segmented flow within the flow cell of the invention is predominantly determined by the Bond number. The critical Bond number Bo_{critical} defines the macro-to-micro scale transition.

Interfacial tension between the FC-72 oil and a range of organic solvents was measured using a pendant-drop tensiometry setup, as shown in FIG. 8. One end of a transfer tubing 56 ( 1/16″ outer diameter, 250 μm inner diameter) was positioned inside an optical cuvette 58 that was pre-filled with the lower density fluid phase to reduce buoyancy effects. The other end of the transfer tubing 56 was connected to a syringe pump 60 containing the other fluid phase, so that operating the syringe pump 60 enables formation of a droplet of the other fluid phase at the end of the transfer tubing 56 inside the optical cuvette 58. The droplet formation was recorded using a light source 62 and diffuser 64 on one side of the optical cuvette 58 and a camera 66 with 2× objective on the other side of the optical cuvette 58. The most suitable frames were selected based on droplet shape, extracted from the video and analysed with OpenDrop software. The transparent transfer tubing 56 was digitally covered with a black overlay before analysis in order to reduce artefacts in the analysis arising from low and/or varying contrast. Inset B of FIG. 8 shows an example of a DMF droplet 68 suspended in FC-72 oil (with a digitally-added black bar). All measurements were conducted in three-fold and performed at ambient temperature (22° C., thermostatically controlled).

Subsequently, the interfacial tension between a wide range of polar and apolar solvents (water, dimethyl sulfoxide, dimethyl formamide, pyridine, chloroform, dichloromethane, acetonitrile, methanol, butanol, toluene, tetrahydrofuran, ethanol, acetone, isopropanol and cyclohexane) and the FC-72 oil was measured. FIG. 9 and Table 3 show experimental interfacial tensions between each of the solvents (continuous phase) and the FC-72 oil (dispersed phase). Table 3 further shows calculated Bond numbers at a characteristic length of 3.0 mm of the channel of the flow cell. All measurements are shown in mean±standard deviation (N=3). Values ranged from 49.0 mN·m⁻¹ for water to 2.6 mN·m⁻¹ for cyclohexane and 3.9 mN·m⁻¹ for 2-propanol, correlating with their relative polarity.

TABLE 3

| | | Experimental | |
|---|---|---|---|
| | Density | interfacial | |
| | difference, | tension, γ | Bond number |
| Droplet phase | Δρ (kg/m³) | (mN · m⁻¹) | (D = 3.0 mm) |
| Water | 683 | 49.0 ± 0.7 | 1.2 |
| Dimethyl sulfoxide | 580 | 19.4 ± 0.09 | 2.5 |
| N,N-Dimethylformamide | 736 | 13.5 ± 0.06 | 4.6 |
| Pyridine | 802 | 11.2 ± 0.2 | 5.3 |
| Chloroform | 191 | 3.0 ± 0.05 | 5.4 |
| Dichloromethane | 350 | 5.2 ± 0.05 | 5.7 |
| Acetonitrile | 894 | 10.4 ± 0.05 | 7.3 |
| Methanol | 888 | 7.1 ± 0.17 | 10.6 |
| n-Butanol | 870 | 6.0 ± 0.11 | 12.3 |
| Toluene | 713 | 5.3 ± 0.08 | 13.1 |
| Tetrahydrofuran | 791 | 5.0 ± 0.13 | 13.5 |
| Ethanol | 891 | 5.5 ± 0.17 | 13.8 |
| Acetone | 895 | 4.6 ± 0.13 | 16.3 |
| 2-Propanol | 894 | 3.9 ± 0.13 | 19.4 |
| Cyclohexane | 779 | 2.6 ± 0.08 | 30.2 |

Since the density differences Δρ for each solvent-FC-72 oil segmented flow system, the characteristic length (inner diameter) of the channel of the flow cell and specific interfacial tensions for each solvent-FC-72 oil segmented flow system are known, the individual Bond numbers can be calculated as shown in FIG. 10.

The segmented flow behaviour in the flow cell at various Bond numbers was tested with 3.0 mm inner diameter flow cells and varying compositions of acetonitrile-water mixtures (ranging from 0 to 100% acetonitrile) with an added dye for visualisation, as shown in FIG. 11A. FIGS. 11B to 11E show flow regimes for acetonitrile-water mixtures at different Bond numbers. For a Bo<3.8, the sample segment stayed intact as it passed through the flow cell (FIG. 11B). For a Bo=4, the sample segment showed either frothing (i.e. break-off of a portion at the rear end of the sample segment) (FIG. 11C) or fragmentation into multiple pieces (FIG. 11D). For a Bo>4.2, the sample segment remained buoyant at the inlet and would not traverse down the flow cell (FIG. 11E).

The Bond number can be reduced below its critical value by either choosing different solvent-FC-72 oil combinations to reduce the ratio of Δρ to σ or by reducing the inner diameter of the channel of the flow cell. The latter is more effective since it does not limit the choice of solvents and fluorocarbon oils.

The relationship between segmented flow behaviour and Bond number was further assessed with 14 non-deuterated solvents (water, dimethyl sulfoxide, dimethyl formamide, pyridine, chloroform, dichloromethane, acetonitrile, methanol, butanol, toluene, tetrahydrofuran, ethanol, acetone and isopropanol) in flow cells with 3.0, 2.0 and 1.7 mm inner diameters. These 14 solvents were selected as they are available in deuterated form, which is important for NMR analysis.

The Bond number data for the 14 solvents shown in FIG. 12 shows that reducing the channel inner diameter and therefore the Bond number enables the flow cell of the invention to be used with solvent-fluorocarbon oil segmented flow systems having relatively low interfacial tension, ranging from two solvents for the 3.0 mm inner diameter flow cell to eight solvents for the 1.7 mm inner diameter flow cell.

For the flow cell of 3.0 mm inner diameter, water and dimethyl sulfoxide resulted in intact sample segments (FIG. 12A). For the flow cell of 2.0 mm inner diameter, water, dimethyl sulfoxide, dimethyl formamide, pyridine, chloroform and acetonitrile resulted in intact sample segments, with dichloromethane left a single trailing droplet behind, while methanol left numerous trailing droplets behind (FIG. 12B). For the flow cell with 1.7 mm inner diameter, water, dimethyl sulfoxide, dimethyl formamide, pyridine, chloroform, dichloromethane, acetonitrile and methanol resulted in intact sample segments while butanol left numerous trailing droplets behind (FIG. 12C). For each of the flow cells, the remaining solvents remained buoyant at the inlet of the flow cell (FIGS. 12A, 12B and 12C).

Therefore, for all solvents except dichloromethane, the Bond number showed to be a good prediction of the segmented flow behaviour. Dichloromethane still exhibited frothing and break-up at a Bo of approximately 3. This is most likely due to the interaction of dichloromethane with the PCTFE surface because both dichloromethane and PCTFE are halogenated.

These observations indicate a transition, or a critical Bond number Bo_{critical} of 4.0, at which the buoyancy of the sample segment dominates the segmented flow behaviour so that the sample segment no longer traverses the flow cell. Below this critical number, sample segments remain intact and can be used for segmented flow NMR analysis. Above this critical number, sample segments float at the top of the flow cell which not only leads to incomplete filling of the active measurement region in the NMR and thereby disturbance in the analysis but also causes significant sample-to-sample carryover.

Respecting the critical Bond number Bo_{critical} by a small margin, the maximum diameter Dₘₐₓ of the flow cell with respect to a given solvent-fluorocarbon oil segmented flow system can be calculated from:

$${D}_{max} = 1000 \sqrt{\frac{3.8 γ}{1000 Δ ρ g}}$$

Table 4 shows predicted maximum flow cell diameter numbers for 14 deuterated solvents, assuming a maximum Bond number of 3.8. It should be noted that the density differences Δρ were calculated for deuterated solvents in this prediction, as opposed to the non-deuterated solvents in previous experiments, and that deuterated solvents have a higher density than their non-deuterated counterparts.

TABLE 4

| | Maximum flow cell |
|---|---|
| Deuterated Solvent | diameter, Dₘₐₓ (mm) |
| Heavy water | 5.8 |
| Dimethyl sulfoxide-d₆ | 3.9 |
| N,N-Dimethylformamide-d₇ | 2.8 |
| Pyridine-d₅ | 2.6 |
| Chloroform-d | 2.5 |
| Dichloromethane-d₂ | 2.5 |
| Acetonitrile-d₃ | 2.2 |
| Methanol-d₄ | 1.9 |
| n-Butanol-d₁₀ | 1.7 |
| Toluene-d₈ | 1.7 |
| Tetrahydrofuran-d₈ | 1.7 |
| Ethanol-d₆ | 1.6 |
| Acetone-d₆ | 1.5 |
| Propanol-d₈ | 1.4 |

Knowledge of both the critical Bond number Bo_{critical} and the interfacial tension of any given solvent-FC-72 oil segmented flow system therefore provides a tool for matching an inner diameter of the channel of the flow cell with a wider range of target solvents.

In the case of a segmented flow with deuterated acetone as the sample solvent and FC-72 as the continuous fluid phase, a Bond number of 3.8 (<Bo_{critical}) is expected for a flow cell with an internal diameter of 1.5 mm, while a Bond number of 15.4 (>>Bo_{critical}) is expected for a flow cell with an internal diameter of 3.0 mm.

A PCTFE flow cell with an internal diameter of 1.5 mm was constructed using compression moulding with an active volume of approximately 39 μL for a proof-of-concept NMR experiment. FIG. 13 shows 500 MHz 1H NMR overlaid spectra for samples dissolved in acetone, namely 1,4-dimethoxybenzene (DMB, FIG. 13A) and 4-nitrotoluene (PNT, FIG. 13B). All peaks are referenced to the resonance of tetramethylsilane (TMS) at 0 ppm. For DMB, characteristic peaks at 6.83 and 3.75 ppm can be identified while remaining peaks originate from non-deuterated acetone and the internal standard TMS. For PNT, multiplet peaks in the 7.3-8.2 ppm region and a peak around 2.46 ppm can be recognised while the remaining signals again originate from the non-deuterated acetone and the internal standard TMS.

In contrast, conventional flow cells with internal diameters of 3.0 mm are only compatible with water and dimethyl sulfoxide as solvent types.

Whilst the reduction in inner diameter of the channel of the flow cell increases the range of compatible solvent-FC-72 oil segmented flow systems, the reduction in inner diameter of the channel of the flow cell also results in a corresponding reduction in the volume of the channel and therefore the absolute number of molecules in the flow cell. This may cause a loss of mass sensitivity in the fluid analysis, particularly due to the volume of the flow cell being proportional to the square of the inner diameter of the channel of the flow cell.

Any loss in mass sensitivity could be compensated by increasing the number of scans and thereby fluid analysis time by the same factor.

Alternatively, to limit the loss in mass sensitivity arising from the reduction in channel inner diameter, the flow cell may include a plurality of channels 70 within the same footprint to increase the absolute number of molecules in the flow cell available for flow-NMR measurement. FIG. 14 shows cross-sectional views of exemplary flow cells having different numbers of channels 70 within the same footprint. To facilitate transfer of the sample segment into and out of the flow cell, the multiple channels 70 are connected to the inlet and outlet transfer tubing via a flow splitter and a flow collector respectively.

Preferably the plurality of channels are formed in a monolithic flow cell structure to define parallel fluid flow paths, intersecting fluid flow paths or a combination of parallel fluid flow paths and intersecting fluid flow paths through the flow cell. This may be achieved through an additive manufacturing or 3D printing process or an injection moulding process to construct the multi-channel flow cell from PCTFE.

In this way, the inner diameter of each channel 70 can be selected to take advantage of sub-critical Bond numbers for a wide range of solvents, and the number of channels 54 in the flow cell can be selected to partially compensate for the loss in mass sensitivity arising from the reduction in the absolute number of molecules in the flow cell.

A microfluidic device according to a second embodiment of the invention is shown in FIG. 15 and is designated generally by the reference numeral 130. FIG. 15a shows a perspective view of the microfluidic device 130, while FIG. 15b shows a cross-sectional view of the microfluidic device 130.

The microfluidic device 130 comprises a flow cell 136 that is constructed of 3M™ Dyneon™ Fluoroplastic THV that is a fluoroplastic composed of tetrafluoroethylene, hexafluoropropylene and vinylidene fluoride. It is envisaged that the Dyneon™ THV material may be replaced by any other fluorinated polymer material, preferably a fluorinated thermoplastic polymer material. As shown in FIG. 15, the flow cell 136 consists of three separate pieces in the form of a flow cell inlet connector 144, a flow cell outlet connector 146 and a flow cell chamber 148.

The flow cell inlet and outlet connectors 144,146 are formed as first and second frame portions that are matingly connected to each other to form a rectangular frame. Other shapes, e.g. square, of the frame are envisaged. The flow cell chamber 148 is dimensioned to fit inside the frame so that it is held in place between the flow cell inlet and outlet connectors 144,146.

The microfluidic device 130 further includes a clamping mechanism. The clamping mechanism includes a U-shaped holder and a pair of support beams 172.

The U-shaped holder comprises a pair of legs 174 interconnected by an intermediate handle 176. Free ends of the legs 174 are pivotally mounted on respective opposite sides of the flow cell inlet connector 144 so that the legs 174 of the U-shaped holder flank the flow cell intlet connector 144.

Each support beam 172 has a first end and a second end. The first ends of the support beam 172 are pivotally mounted on respective opposite sides of the flow cell outlet connector 146. The second ends of the support beams 172 are pivotally attached to the ends of the respective legs 174 of the U-shaped holder that are adjacent to respective ends of the handle 176.

In use, the clamping mechanism is operable by pushing down on the handle 176 to pivot the legs 174 and support beams 172 towards the flow cell inlet and outlet connectors 144,146 respectively so that the legs 174 and support beams 172 are overlappingly aligned along the sides of, and in-plane relative to, the flow cell inlet and outlet connectors 144,146. This has the effect of clamping the flow cell inlet and outlet connectors 144,146 together to form the frame and hold the flow cell chamber 148 between the flow cell inlet and outlet connectors 144,146.

To release the flow cell inlet and outlet connectors 144,146 from each other and thereby release the flow cell chamber 148, the clamping mechanism is operable by pulling the handle 176 to pivot the legs 174 and support beams 172 away from the flow cell inlet and outlet connectors 144,146 respectively so that the legs 174 and support beams 172 are positioned out of plane relative to the flow cell inlet and outlet connectors 144,146.

It is envisaged that, in other embodiments of the invention, the clamping mechanism may be replaced by a different type of clamping mechanism or a different type of securing or fastening arrangement in order to releasably hold the flow cell inlet and outlet connectors 144,146 together to form the frame. It is also envisaged that, in still other embodiments, the flow cell inlet and outlet connectors 144,146 may be permanently held together to form the frame.

The flow cell inlet connector 144 includes a plurality of inlet bores 178. A respective inlet transfer tubing 138 is received in the respective inlet bore 178 of the flow cell inlet connector 144 using a one-piece nut-and-ferrule connection. The flow cell outlet connector 146 includes a plurality of outlet bores 180. A respective outlet transfer tubing 140 is received in the respective outlet bore 180 of the flow cell outlet connector 146 using a one-piece nut-and-ferrule connection.

The flow cell chamber 148 includes an intermediate chamber that is arranged between inlet and outlet portions. The flow cell chamber 148 defines a plurality of channels, each of which extends from the inlet portion, through the intermediate chamber and to the outlet portion. The plurality of channels are arranged to define parallel fluid flow paths, intersecting fluid flow paths or a combination of parallel fluid flow paths and intersecting fluid flow paths through the flow cell chamber 148. It is envisaged that, in other embodiments of the invention, the flow cell chamber 148 may define a single channel.

The flow cell 136 may be fabricated by first creating a master mould via micromilling and then pouring melted 3M™ Dyneon™ Fluoroplastic THV 500GZ pellets into the master mould to create a plastic layer with the desired layout of internal bores 178,180 and channels. Multiple moulded THV 500GZ plastic layers can be created in this manner. This is followed by bonding of different moulded THV 500GZ plastic layers by first spin-coating thin layers of 3M™ Dyneon™ Fluoroplastic THV 200G pellets dissolved in acetone onto the moulded THV 500GZ plastic layers and then pressing the moulded THV 500GZ plastic layers together using a hot press where the spin-coated thin THV 200G plastic layers act as intermediate bonding layers between the moulded THV 500GZ plastic layers.

When the flow cell chamber 148 is held between the flow cell inlet and outlet connectors 144,146, a first end of each channel at the inlet portion is fluidly connected to a respective inlet bore 178 of the flow cell inlet connector 144, and a second end of each channel at the outlet portion is fluidly connected to a respective outlet bore 180 of the flow cell outlet connector 146. In this way fluid can flow through the flow cell 136 by entering the flow cell 136 through the flow cell inlet connector 144, passing through the channels in the flow cell chamber 148 and exiting the flow cell 136 through the flow cell outlet connector 146.

A respective segmented flow is created by introducing one or more sample segments (‘slugs’ or ‘plugs’) into a continuous flow of fluorinated oil carrier, exemplarily Fluorinert® FC-72 oil, so that the sample segment is bracketed by the FC-72 oil. The sample segment and FC-72 oil are immiscible to enable segmented flow. The sample segment is transferred from a source, e.g. a robotic autosampler, into the flow cell 136, by way of displacement by a discrete volume of FC-72 oil through each inlet transfer tubing 138. Each sample segment is positioned inside the channels in the intermediate chamber of the flow cell chamber 136 to enable measurement or processing of the sample segment. When each sample segment is in position inside the intermediate chamber, temperature equilibration may be carried out for a set period of time before carrying out the measurement or processing. After the measurement or processing procedure is complete, each sample segment is then transferred out of the flow cell 136 via the respective outlet transfer tubing 140 to the waste fluid container.

Details of the segmented flow described above with reference to the first embodiment shown in FIG. 1 apply mutatis mutandis to the second embodiment shown in FIG. 15.

The microfluidic device 130 may further include electrodes 182 formed on the flow cell chamber 136. In use, the electrodes 182 are connected to an electrical circuit to enable one or more electrically driven processes to be carried out inside the flow cell chamber 136. Non-limiting examples of electrically driven processes include electrohydrodynamics, electroextraction, electrolysis, electrophoresis and electrokinetically driven sample transfer.

Non-limiting applications of the microfluidic device 130 of FIG. 15 include:
a modular “analytical toolbox” for sample preparation prior to measurement such as mass spectroscopy (MS) or NMR;
hyphenated steps in analytical workflow, sampling, sample preparation, sample separation, and MS or NMR analysis;
active processing of the sample segment inside the flow cell chamber, including: cell manipulation (lysis); extraction (electroextraction, liquid-liquid extraction and solid-phase extraction); mixing (derivatization, addition of reagents, and enzymatic digestion); polymerase chain reaction; sorting and splitting.

The configuration of the microfluidic device 130 of FIG. 15 enables replacement of the various components of the microfluidic device 130 as required. In particular, the flow cell chamber 148 may be replaced by another flow cell chamber having a different layout and/or number of channels for use with different fluidic applications.

It was observed that machining methods, such as turning and reaming, inherently leave machining marks on the machined surfaces. The resulting surface roughness results in local inhomogeneity in the magnetic field, which in turn compromises the spectral quality.

To improve spectral quality, the machined PCTFE flow cells underwent thermal compression moulding after the machining step. For compression moulding, a solid, highly-polished steel core mould was inserted into the flow cell chamber 48, and the assembly was placed in a heated compression chamber. By heating the flow cell chamber 48 to above glass transition temperature (and either below or slightly above melting temperature and compressing the flow cell around the core mould, the surface quality of the highly-polished core mould was transferred to the interior walls of the flow cell chamber 48. Natural cooling to room temperature under compression then allowed the polymer chains to set in their final shape with minimal internal stress. The core mould may optionally also include features corresponding to the inlet portion 48c with the tapered conical bore transition to the flow chamber 48. Therefore, as an added advantage, the compression moulding process can optionally be used to smooth out small machining defects in the inlet portion 48c too to ensure a smooth flow transition. Otherwise internal surface defects in the inlet portion 48c may lead to perturbations in the segmented flow.

PCTFE flow cells manufactured by thermal compression moulding displayed a high-quality, mirror-like surface finish on its interior walls. Accordingly the spectral quality of these flow cells was improved. For the sucrose doublet at 5.40 ppm, 42% line splitting was obtained with the machined and thermal compression moulded PCTFE flow cell compared to 59% line splitting for the machined PCTFE flow cell. Likewise, a peak width at 50% peak height for maleic acid (chemical shift signal of 6.02 ppm) of 1.83 Hz was observed for the machined and thermal compression moulded PCTFE flow cell compared to 2.13 Hz for the machined flow cell.

FIG. 16 shows 500 MHz 1H NMR overlaid spectra of the sucrose doublet at 5.40 ppm for the machined PCTFE flow cell (indicated by ‘200’) and the machined and thermal compression moulded PCTFE flow cell (indicated by ‘300’). All peaks are referenced to the resonance of DSS at 0 ppm.

Table 5 shows the peak width at indicated peak height (%) for 17 mM maleic acid for a glass flow cell (comparative example), a machined PCTFE flow cell and a machined and thermal compression moulded PCTFE flow cell.

TABLE 5

| | Chemical | | |
|---|---|---|---|
| | Shift | | |
| Sample | signal | Flow cell | Peak width (Hz) at indicated |
| type | (ppm) | material | peak height (%) n = 48 |
| 17 mM | 6.02 | Glass | 1.19 ± 0.10 (50%), 16.17 ± 0.90 |
| Maleic | | (Comparative | (0.55%), 31.80 ± 2.05 (0.11%) |
| acid | | Example) | |
| | | PCTFE | 2.13 ± 0.25 (50%), 21.49 ± 0.89 |
| | | (machined) | (0.55%), 40.16 ± 2.43 (0.11%) |
| | | PCTFE | 1.83 ± 0.03 (50%), 17.49 ± 0.31 |
| | | (machined | (0.55%), 35.59 ± 1.33 (0.11%) |
| | | and thermal | |
| | | compression | |
| | | moulded | |

The configuration of the flow cell of the invention provides at least the following benefits:
a) Interchangeability of flow cells: Constructing the flow cell out of releasable connections enables easy replacement of the flow cell while the transfer tubing stays in place.
b) Variability of the flow cell's inner diameter to accommodate a wide range of solvents.
c) Variability of the flow cell's inner diameter to accommodate lower sample volumes: NMR spectroscopy requires a minimum height of sample to be filled in the measurement region (or detection zone). A smaller inner diameter reduces sample volume required to fill the measurement region, which can be crucial for samples of limited volume.
d) Fabrication of PCTFE flow cells to comprise a plurality of channels: Reducing the flow cell's inner diameter reduces measurement sensitivity of the NMR spectroscopy. On the other hand the provision of multiple channels (such as parallel channels), each with an individual inner diameter equal to, or smaller than, the maximum inner diameter for a given solvent, increases measurement sensitivity when compared to a single channel with the same individual inner diameter.
e) Transition between flow sections with different inner diameters: A small inner diameter is preferred in transfer tubing for fast transfer, while a larger inner diameter is preferred for the flow cell in order to maximise sample volume in the measurement region. The inclusion of the tapered bore section(s) in the flow cell permits the use of the preferred relative inner diameters of the transfer tubing and the flow cell while avoiding a sudden transition in inner diameter that could disturb flow behaviour.
f) PCTFE flow cell rigidity: For NMR, the walls of the flow cell is preferably parallel with a bore of the measurement region. The rigidity of the PCTFE flow cell enables it to be readily combined and used with various flow measurement accessories and instruments, which allows for exact, repeatable and reproducible positioning of the flow cell in the measurement region.

Furthermore, with particular comparison to a conventional glass flow cell coated with fluorosilane, the configuration of the flow cell of the invention provides at least the following benefits:
a) Fabrication technique: Thermal compression moulded PCTFE flow cells exhibited improved spectral quality and performance when compared to machined PCTFE flow cells. This is due to surface roughness produced by machining, which caused local magnetic field inhomogeneities and thereby reducing measurement quality. On the other hand, thermal compression moulding after machining polishes the inner surface of the flow cell to a high degree of smoothness to produce the improved spectral quality and performance.
b) Material properties: PCTFE is less fragile than glass, which reduces the risk of breaking the flow cell during handling. PCFTE has a permanent fluoropolymer character, which removes the need for a regular coating process that not only adds time and costs but also raises issues of homogeneity, repeatability, reproducibility and coating degradation over time.
c) Production process: Creating flow cells with varying geometries is easier and more repeatable in PCTFE compared to glass. Also, working with fluoropolymer allows for large-scale industrial manufacturing.
d) Internal geometry: It is difficult to manufacture glass flow cells with multiple parallel or interconnected channels in a consistent and repeatable manner.

It will be appreciated that numerical parameters are merely chosen as examples to help illustrate the working of the invention and are not intended to be limiting on the scope of the invention.

It is envisaged that, in other embodiments of the invention, the flow cell and/or the transfer tubing may be constructed of another fluoropolymer material. It is also envisaged that, in still other embodiments of the invention, the FC-72 oil may be replaced by a different fluorinated fluid carrier.

Preferences and options for a given aspect, feature or parameter of the invention should, unless the context indicates otherwise, be regarded as having been disclosed in combination with any and all preferences and options for all other aspects, features and parameters of the invention.

1. A fluidic assembly comprising a fluid analysis apparatus, the fluid analysis apparatus comprising:
a fluid measurement device;
a fluidic device including a flow cell arranged in a measurement region of the fluid measurement device, the flow cell constructed of at least one first fluoropolymer material, the flow cell including a channel, the channel containing a sample segment that is carried in a fluorinated fluid carrier, wherein the sample segment and fluorinated fluid carrier are immiscible.

2. A fluidic assembly comprising a fluidic device, the fluidic device including a flow cell that is formed of at least two discrete fluidly connected flow cell components, each flow cell component constructed of a first fluoropolymer material, the flow cell including a channel, the channel containing a sample segment that is carried in a fluorinated fluid carrier, wherein the sample segment and fluorinated fluid carrier are immiscible.

3. The fluidic assembly according to claim 2 wherein the flow cell is formed of at least two discrete releasably and fluidly connected flow cell components and/or wherein the flow cell is formed of at least two discrete non-releasably and fluidly connected flow cell components.

4. The fluidic assembly according to claim 1 wherein the fluidic device is a microfluidic device.

5. The fluidic assembly according to claim 1 wherein the or each first fluoropolymer material is polychlorotrifluoroethylene.

6. The fluidic assembly according to claim 1 wherein the sample segment is a solvent or a deuterated solvent.

7. (canceled)

8. The fluidic assembly according to claim 1 wherein the fluorinated fluid carrier is a fluorocarbon oil carrier.

9. (canceled)

10. (canceled)

11. The fluidic assembly according to claim 1 wherein the flow cell includes a plurality of channels, and the plurality of channels are arranged to define parallel fluid flow paths, intersecting fluid flow paths or a combination of parallel fluid flow paths and intersecting fluid flow paths through the flow cell.

12. The fluidic assembly according to claim 1 wherein the flow cell includes a plurality of channels, and the plurality of channels are formed in a monolithic flow cell structure.

13. The fluidic assembly according to claim 1 wherein the sample segment, the fluorinated fluid carrier and a characteristic length of the channel are selected to correspond to a Bond number that corresponds to the sample segment staying intact as it is carried by the fluorinated fluid carrier through the channel.

14. The fluidic assembly according to claim 13 wherein the Bond number is lower than 4.0.

15. The fluidic assembly according to claim 1 wherein the flow cell is formed of at least two discrete fluidly connected flow cell components, each flow cell component constructed of a first fluoropolymer material.

16. The fluidic assembly according to claim 15 wherein the flow cell is formed of at least two discrete releasably and fluidly connected flow cell components and/or wherein the flow cell is formed of at least two discrete non-releasably and fluidly connected flow cell components.

17. The fluidic assembly according to claim 1 wherein the flow cell comprises:
a flow cell inlet connector defining an inlet for fluid connection to a first fluid conduit;
a flow cell outlet connector defining an outlet for fluid connection to a second fluid conduit; and
a flow cell chamber including a intermediate chamber arranged between inlet and outlet portions, the inlet portion of the flow cell chamber fluidly connected to the flow cell inlet connector, the outlet portion of the flow cell chamber fluidly connected to the flow cell outlet connector.

18. The fluidic assembly according to claim 17 wherein the inlet portion of the flow cell chamber is releasably and fluidly connected to the flow cell inlet connector, and/or wherein the outlet portion of the flow cell chamber is releasably and fluidly connected to the flow cell outlet connector.

19. (canceled)

20. (canceled)

21. (canceled)

22. (canceled)

23. The fluidic assembly according to claim 17 wherein the flow cell inlet connector is formed as a first frame portion, the flow cell outlet connector is formed as a second frame portion, and the first and second frame portions are engageable with each other to form a frame for holding the flow cell chamber between the flow cell inlet and outlet connectors.

24. The fluidic assembly according to claim 1 including first and second fluid conduits constructed of a second fluoropolymer material, wherein an inlet of the fluidic device is fluidly coupled to the first fluid conduit, and an outlet of the fluidic device is fluidly coupled to the second fluid conduit.

25. (canceled)

26. (canceled)

27. A method of configuring a fluidic assembly, the fluidic assembly in accordance with claim 1, the method comprising the steps of:
providing a fluid measurement device;
providing a flow cell constructed of at least one first fluoropolymer material, the flow cell including a channel;
arranging the flow cell in a measurement region of the fluid measurement device; and
supplying a sample segment carried in a fluorinated fluid carrier into the channel of the flow cell, wherein the sample segment and fluorinated fluid carrier are immiscible.

28. (canceled)

29. A method of configuring a fluidic assembly, the fluidic assembly in accordance with claim 2, the method comprising the steps of:
providing a fluidic device, the fluidic device including a flow cell that is formed of at least two discrete fluidly connected flow cell components, each flow cell component constructed of a first fluoropolymer material, the flow cell including a channel; and
supplying a sample segment carried in a fluorinated fluid carrier into the channel of the flow cell, wherein the sample segment and fluorinated fluid carrier are immiscible.

30. The method according to claim 27 including the step of performing a machining process or an additive manufacturing or 3D printing process or an injection moulding, compression moulding or thermoforming process to construct at least one component of the flow cell from the or each first fluoropolymer material.
